(19) United States
(12) Patent Application Publication
(10) Pub. No.: US 2026/0276735 A1
(43) Pub. Date: Sep. 17, 2026

(54) DETECTION CIRCUIT AND DETECTION METHOD

(71) Applicant: NOVATEK Microelectronics Corp., Hsin-Chu (TW)

(72) Inventor: Wei-Jen Lin, Tainan City (TW)

(73) Assignee: NOVATEK Microelectronics Corp, Hsin-Chu (TW)

(21) Appl. No.: 19/075,814

(22) Filed: Mar. 11, 2025

(51) Int. Cl. G01R 31/52; G09G 3/00; H03K 5/24; H03K 19/21

(52) U.S. Cl. CPC G01R 31/52; G09G 3/006; H03K 5/24; G09G 2300/0408; G09G 2330/04; G09G 2330/12; H03K 19/21

(57) ABSTRACT

A detection circuit for a driving circuit is provided. The detection circuit includes a comparison circuit and a logic circuit. The comparison circuit is coupled to an output pin of the driving circuit. The comparison circuit is configured to receive an output from the output pin, compare the output signal with a first reference signal level to generate a first comparison result, and compare the output signal with a second reference signal level to generate a second comparison result The first reference signal level is different from the second reference signal level. The logic circuit is configured to generate a detection result according to the first comparison result and second comparison result in order to indicate whether a short circuit condition occurs between the output pin and an adjacent output pin of the driving circuit.

### BACKGROUND OF THE INVENTION

The present invention relates to a detection circuit and a detection method, and more particularly, to a detection circuit capable of detecting short circuit condition and a detection method thereof.

In general, for ensuring the quality and functionality of electronic products with displaying function, product manufacturers usually perform many normal function inspections for the electronic products during the manufacturing process or after manufacturing in order to verify whether the electronic products can operate normally. One of the most common problems encountered in the maintenance of electric products is short circuit. Further, display devices, such as liquid crystal displays (LCDs), are widely applied in various electronic products. For example, please refer to FIG. 1, which is a schematic diagram of a display device 1 in the related prior art. In the display device 1, the driving circuit 102 may be used to drive the display panel 104 for displaying image data. The driving circuit 102 includes a plurality of output pins CGOUT for outputting output driving signals. Each output pin CGOUT may be electrically connected to the display panel 104 through a chip-on-film (COF) package component 106 mounted on a film. As such, the output signals may be transmitted from the output pins CGOUT of the driving circuit 102 to the display panel 104 through the COF package components 106. Once the COF package component 106 is damaged or broken, an unexpected electrical connection between two neighboring output pins may occur, and a short-circuit condition may exist between the two neighboring output pins simultaneously, thus resulting in circuit damage and malfunction or overheating of the display device 1. Thus, how to provide a better fault inspection scheme for the display device has become an important issue in this art.

### SUMMARY OF THE INVENTION

It is therefore an objective of the present invention to provide a detection circuit capable of detecting short circuit condition and a detection method thereof, to solve the abovementioned problem.

According to an embodiment of the present invention, a detection circuit for a driving circuit is provided. The detection circuit comprises: a comparison circuit, coupled to an output pin of the driving circuit, and configured to receive an output signal from the output pin of the driving circuit, compare the output signal with a first reference signal level to generate a first comparison result, and compare the output signal with a second reference signal level to generate a second comparison result, wherein the first reference signal level is different from the second reference signal level; and a logic circuit, coupled to the comparison circuit, and configured to generate a detection result according to the first comparison result and second comparison result in order to indicate whether a short circuit condition occurs between the output pin and an adjacent output pin of the driving circuit.

According to an embodiment of the present invention, a detection method for a driving circuit is provided. The detection method comprises: receiving an output signal from an output pin of the driving circuit; comparing the output signal with a first reference signal level to generate a first comparison result; comparing the output signal with a second reference signal level to generate a second comparison result, wherein the first reference signal level is different from the second reference signal level; and generating a detection result according to the first comparison result and second comparison result in order to indicate whether a short circuit condition occurs between the output pin and an adjacent output pin of the driving circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a display device in the related prior art.

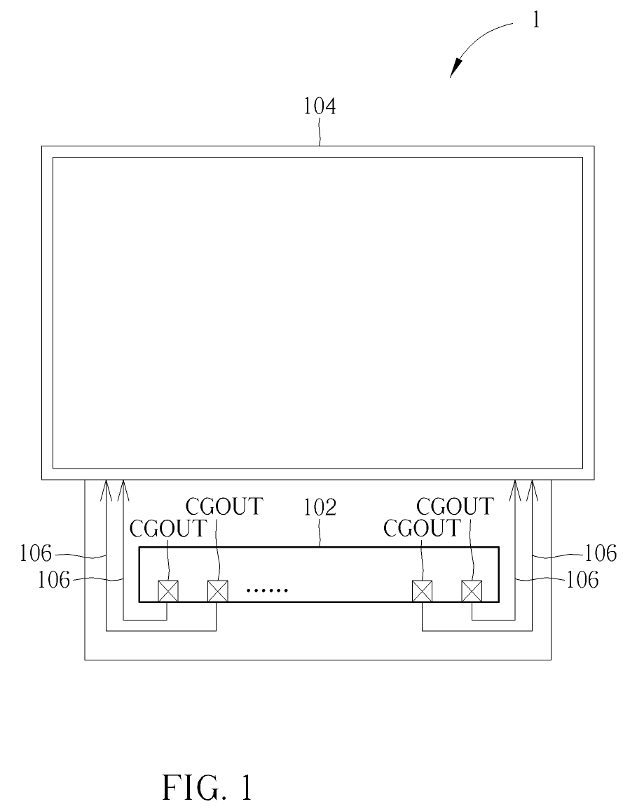

FIG. 2 is a schematic diagram of a display device according to an embodiment of the present invention.

FIG. 3 is a schematic diagram of the detection circuit of the display device shown in FIG. 2 according to an embodiment of the present invention.

FIG. 4 is a schematic diagram illustrating output signals of output pins during a normal state and an occurrence of short circuit condition according to an embodiment of the present invention.

FIG. 5 is a schematic diagram illustrating operations of the deglitch circuit in the detection circuit according to an embodiment of the present invention.

FIG. 6 is a schematic diagram illustrating operations of the counter circuit in the detection circuit according to an embodiment of the present invention.

FIG. 7 is a schematic diagram illustrating arrangement of the detection circuits and the output pins according to an alternative embodiment of the present invention.

FIG. 8 is a schematic diagram of the detection circuit of the display device shown in FIG. 2 according to an alternative embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to …”. Also, the term “couple” is intended to mean either an indirect or direct electrical connection. Accordingly, if one device is coupled to another device, that connection may be through a direct electrical connection, or through an indirect electrical connection via other devices and connections.

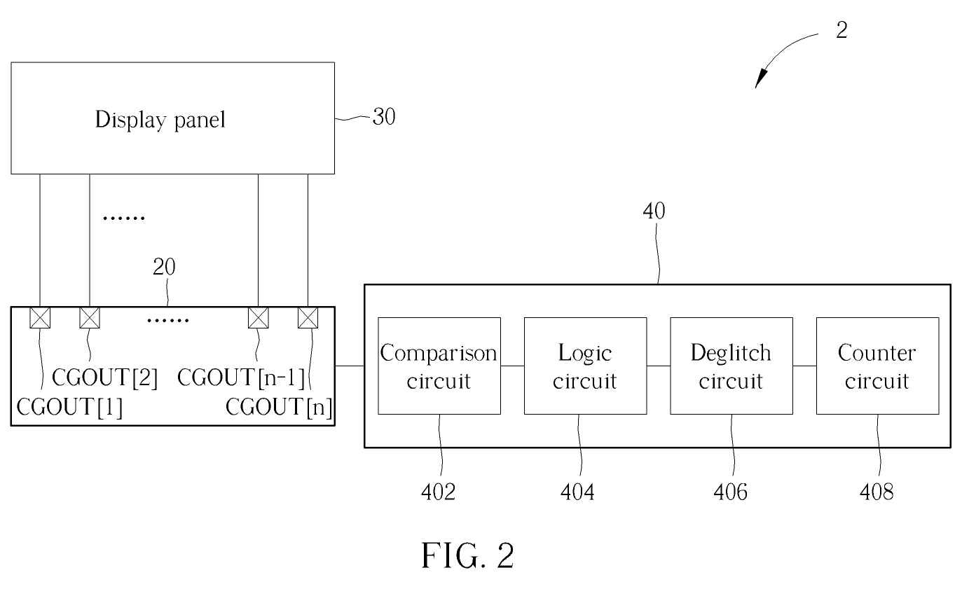

Please refer to FIG. 2, which is a schematic diagram of a display device 2 according to an embodiment of the present invention. The display device 2 may be utilized in an electronic product, such as smart phone, laptop, tablet, television or television. The display device 2 includes a driving circuit 20, a display panel 30 and a detection circuit 40. Based on a design requirement, the display panel 30 may be any type of display panel, for example, a liquid crystal display (LCD) panel, an organic light emitting diode (OLED) display panel, a mini-LED panel, or a micro-LED panel, but not limited thereto. The display panel 30 may include a plurality of pixels arranged in a matrix pattern.

The driver circuit 20 may include output pins CGOUT[0] to CGOUT[n]. The driver circuit 20 is configured to generate output signals and output the output signals via the output pins CGOUT[0] to CGOUT[n] to drive the pixels of the display panel 30 for performing display operations. For example, the output pins CGOUT[0] to CGOUT[n] may be respectively electrically connected to different gate lines (or referred to as scan lines) of the display panel 30. Each output signal may be outputted to the display panel 30 through the corresponding output pin. The output signal may include a gate driving signal, a gate driver on array (GOA) signal, a scan signal, a control signal and/or any other driving signal or control signal that is capable of driving or controlling pixels of the display panel 30. Besides, the driving circuit 20 may be implemented in an integrated circuit (IC) as a display driver IC (DDIC). The driving circuit 20 may be a GOA circuit or a gate in panel (GIP) circuit. The driving circuit 20 may include a gate driver, a GOA circuit, a source driver, a timing control circuit, and/or other driving circuits according to design requirements.

The detection circuit 40 may be coupled to the driving circuit 20 for determining which output pin of the driving circuit 20 is short circuited with its adjacent output pin based on the output signal from the output pin of the driving circuit 20. In more detail, the detection circuit 40 may be coupled to any of the output pins CGOUT[0] to CGOUT[n] in the driving circuit 20 and receive an output signal from the coupled output pin. The detection circuit 40 is configured to detect whether a short circuit condition occurs between the coupled output pin and its adjacent output pin according to the output signal of the coupled output pin. As shown in FIG. 2, the detection circuit 40 includes a comparison circuit 402, a logic circuit 404, a deglitch circuit 406 and a counter circuit 408. The comparison circuit 402 is be coupled to an output pin of the driving circuit 20 and configured to receive an output signal from the coupled output pin of the driving circuit 20. The comparison circuit 402 is configured to compare the output signal with a first reference signal level to generate a first comparison result and to compare the output signal with a second reference signal level to generate a second comparison result. The first reference signal level may be different from the second reference signal level. The signal level of the output signal may be a voltage level or a current level. The first reference signal level may be a first reference voltage or a first reference current, and the second reference signal level may be a second reference voltage or a second reference current.

The logic circuit 404 is coupled to the comparison circuit 402 and configured to generate a detection result according to the first comparison result and second comparison result in order to indicate whether a short circuit condition occurs on the output pin. The logic circuit 404 may be an exclusive or (XOR) gate circuit, or an or (OR) gate circuit, but not limited thereto. For example, the first reference signal level could be greater than the second reference signal level. When the first comparison result indicates that the signal level of the output signal is small than the first reference signal level and the second comparison result indicates that the signal level of the output signal is greater than the second reference signal level, this means the signal level of the output signal falls within a range between the first reference signal level and the second reference signal level, the logic circuit 404 generates the detection result indicating that the short circuit condition occurs between the output pin and its adjacent pin of the driving circuit 20.

In another embodiment, when the first comparison result indicates that the signal level of the output signal is greater than or equal to the first reference signal level and the second comparison result indicates that the signal level of the output signal is greater than the second reference signal level, the logic circuit 404 generates the detection result indicating that no short circuit condition occurs between the output pin and the adjacent pin of the driving circuit. In another embodiment, when the first comparison result indicates that the signal level of the output signal is small than the first reference signal level and the second comparison result indicates that the signal level of the output signal is small than or equal to the second reference signal level, the logic circuit 404 generates the detection result indicating that there is no short circuit condition occurs between the output pin and the adjacent pin of the driving circuit.

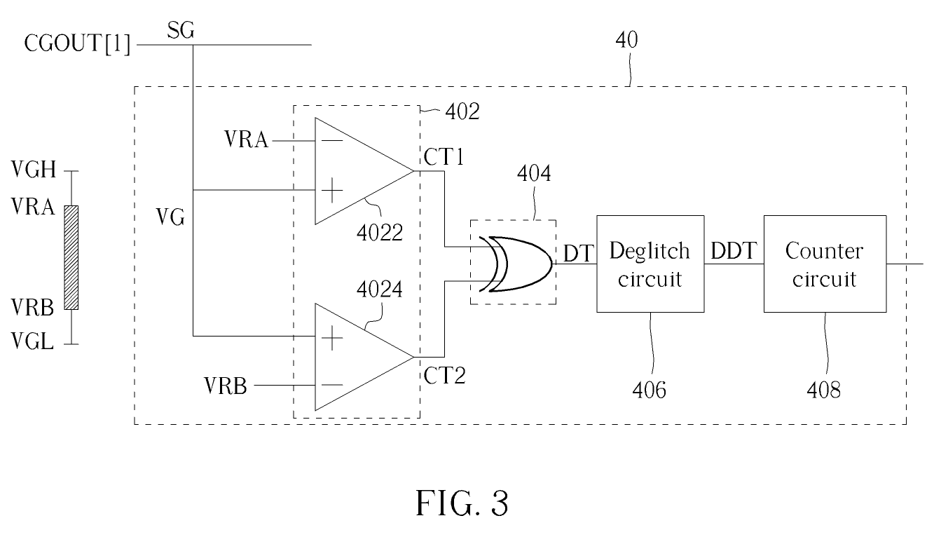

Please refer to FIG. 3. FIG. 3 is a schematic diagram of the detection circuit 40 of the display device 2 shown in FIG. 2 according to an embodiment of the present invention. As shown in FIG. 3, the comparison circuit 402 includes voltage comparators 4022 and 4024. In one embodiment, the first reference signal may be a first reference voltage VRA, and the second reference signal may be a second reference voltage VRB. The first reference voltage VRA may be different from the second reference voltage VRB. For example, the first reference voltage VRA may be greater than the second reference voltage VRB. For example, the first reference voltage VRA may be smaller than or equal to a gate high voltage VGH. The first reference voltage VRA may be set between 0 volt (V) and a gate high voltage VGH. For example, the second reference voltage VRB may be greater than or equal to a gate low voltage VGL. The second reference voltage VRB may be set between 0V and a gate low voltage VGH. The second reference voltage VRB may be set between 0V and the gate low voltage VGL. The output signal SG may be switched between the gate high voltage VGH and the gate low voltage VGL during normal operation.

For brevity of description, the detection circuit 40 is assumed to be coupled to an output pin (e.g., output pin CGOUT[1]) of the driving circuit 20 and detect whether a short circuit condition occurs between the output pin CGOUT[1] and its adjacent pin. A non-inverting input terminal of the comparator 4022 is coupled to an output pin (e.g., output pin CGOUT[1]) of the driving circuit 20 and configured to receive an output signal SG from the output pin CGOUT[1] of the driving circuit 20, and an inverting input terminal of the comparator 4022 is configured to receive a first reference voltage VRA. The comparator 4022 is configured to compare a voltage VG of the output signal SG from the output pin CGOUT[1] with the first reference voltage VRA to generate a comparison result CT1, and output the comparison result CT1 to the logic circuit 404 via an output terminal of the comparator 4022. Moreover, a non-inverting terminal of the comparator 4024 is coupled to the output pin CGOUT[1]) of the driving circuit 20 and configured to receive the output signal SG from the output pin CGOUT[1], and an inverting terminal of the comparator 4024 is configured to receive a second reference voltage VRB. The comparator 4024 is configured to compare the voltage VG of the output signal SG with the second reference voltage VRB to generate a comparison result CT2, and output the comparison result CT2 to the logic circuit 404 via an output terminal of the comparator 4024.

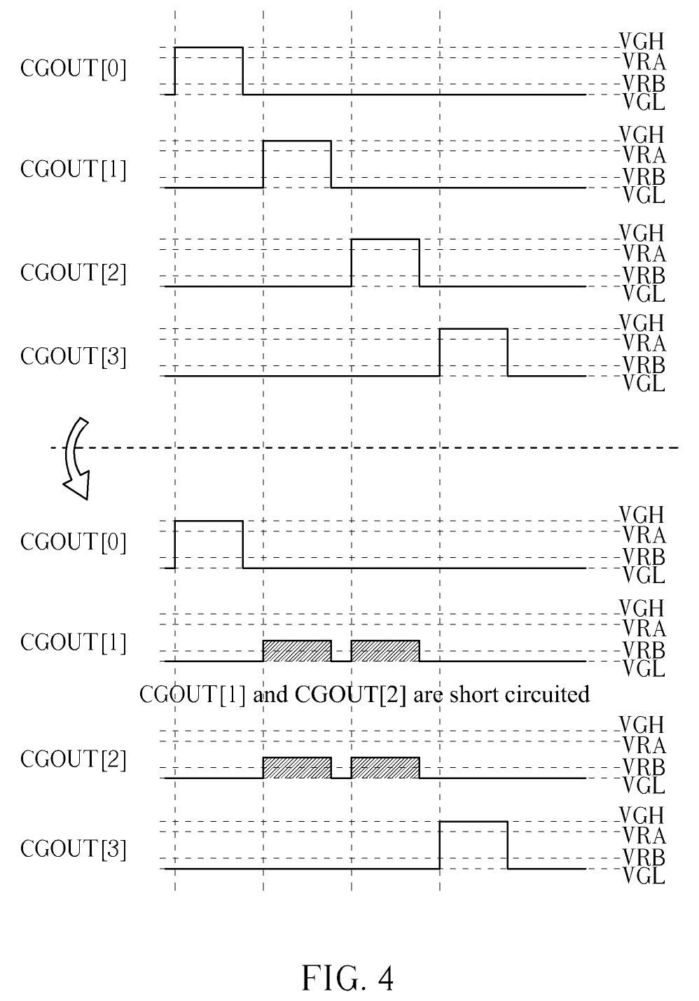

For example, as shown in the upper side of FIG. 4, during normal operation, the driving circuit 20 operates in a normal state, and the output signals of the output pins CGOUT[0] to CGOUT[3] may be switched between the gate high voltage VGH and the gate low voltage VGL. As such, when the comparison result CT1 of the comparator 4022 indicates that the voltage VG of the output signal SG is greater than or equal to the first reference voltage VRA and the second comparison result CT2 of the comparator 4024 indicates that the voltage VG of the output signal SG is greater than the second reference voltage VRB, this means that the voltage VG of the output signal SG is outside the range between the first reference voltage VRA and the second reference voltage VRB since the first reference voltage VRA is greater than the second reference voltage VRB. Accordingly, the logic circuit 404 generates the detection result DT indicating that no short circuit condition occurs between the output pin CGOUT[1] and its adjacent pins. When the comparison result CT1 of the comparator 4022 indicates that the voltage VG of the output signal SG is smaller than the first reference voltage VRA and the second comparison result CT2 of the comparator 4024 indicates that the voltage VG of the output signal SG is smaller than or equal to the second reference voltage VRB, this means that the voltage VG of the output signal SG is outside the range between the first reference voltage VRA and the second reference voltage VRB since the first reference voltage VRA is greater than the second reference voltage VRB. The logic circuit 404 generates the detection result DT indicating that no short circuit condition occurs between the output pin CGOUT[1] and its adjacent pins.

For example, take the output signal SG of the output pin CGOUT[1] as an example for illustration, suppose the normal operating voltage of the gate high voltage VGH is 10V, the normal operating voltage of the gate low voltage VGL is -10V, the first reference voltage VRA could be set to be 8V, and the second reference voltage VRB could be set to be -8V. The logic circuit 404 includes an exclusive or (XOR) gate circuit. In an embodiment, if the detected voltage VG of the output signal SG is 10V, the comparator 4022 outputs the comparison result CT1 of logic “1” indicating that the voltage VG (e.g., 10V) is greater than the first reference voltage VRA (e.g., 8V), and the comparator 4024 outputs the comparison result CT2 of logic “1” indicating that the voltage VG (e.g., 10V) is greater than the second reference voltage VRB (e.g., -8V), and therefore, the logic circuit 404 generates the detection result DT of logic “0” indicating that no short circuit condition occurs between the output pin CGOUT[1] and its adjacent pins. In an embodiment, if the detected voltage VG of the output signal SG is -10V, the comparator 4022 outputs the comparison result CT1 of logic “0” indicating that the voltage VG (e.g., -10V) is smaller than the first reference voltage VRA (e.g., 8V), and the comparator 4024 outputs the comparison result CT2 of logic “0” indicating that the voltage VG (e.g., -10V) is smaller than the second reference voltage VRB (e.g., -8V), and therefore, the logic circuit 404 generates the detection result DT of logic “0” indicating that no short circuit condition occurs between the output pin CGOUT[1] and its adjacent pins.

For example, as shown in the bottom side of FIG. 4, a short circuit condition occurs on the output pin CGOUT[1]. The output pin CGOUT[1] is shorten with the output pin CGOUT[2] and a short circuit condition occurs between the output pin CGOUT[1] and the output pin CGOUT[2]. Voltage levels or signal amplitudes of the output signals of both the output pin CGOUT[1] and the output pin CGOUT[2] may be pulled to unexpected intermediate level. Besides, the output signals of the output pins CGOUT[0] and CGOUT[3] may be switched between the gate high voltage VGH and the gate low voltage VGL. When the comparison result CT1 of the comparator 4022 indicates that the voltage VG of the output signal SG is smaller than the first reference voltage VRA and the second comparison result CT2 of the comparator 4024 indicates that the voltage VG of the output signal SG is greater than the second reference voltage VRB, this means that the voltage VG of the output signal SG falls within the range between the first reference voltage VRA and the second reference voltage VRB since the first reference voltage VRA is greater than the second reference voltage VRB. Therefore, the logic circuit 404 generates the detection result DT indicating that a short circuit condition occurs between the output pin CGOUT[1] and its adjacent pins.

For example, if the detected voltage VG of the output signal SG is 5V, the comparator 4022 outputs the comparison result CT1 of logic “0” indicating that the voltage VG (e.g., 5V) is smaller than the first reference voltage VRA (e.g., 8V), and the comparator 4024 outputs the comparison result CT2 of logic “1” indicating that the voltage VG (e.g., 5V) is greater than the second reference voltage VRB (e.g., -8V), and accordingly, the logic circuit 404 generates the detection result DT of logic “1” indicating that a short circuit condition occurs between the output pin CGOUT[1] and its adjacent pins. For example, if the detected voltage VG of the output signal SG is -5V, the comparator 4022 outputs the comparison result CT1 of logic “0” indicating that the voltage VG (e.g., -5V) is smaller than the first reference voltage VRA (e.g., 8V), and the comparator 4024 outputs the comparison result CT2 of logic “1” indicating that the voltage VG (e.g., -5V) is greater than the second reference voltage VRB (e.g., -8V), and the logic circuit 404 generates the detection result DT of logic “1” indicating that a short circuit condition occurs between the output pin CGOUT[1] and its adjacent pins. When the voltage of the output signal is within the range between the first reference voltage VRA and the second reference voltage VRB, the logic circuit 404 generates the detection result DT indicating that a short circuit condition occurs between the output pin CGOUT[1] and its adjacent pins.

In other words, since the impedance between two adjacent output pins changes, the two pins would be short-circuited with each other, such that the output voltage or signal amplitude of the output pin will be pulled to an unexpected intermediate level. Therefore, the embodiments of the present invention provides the comparison circuit 402 and the logic circuit 404 of the detection circuit 40 to determine the presence of a short circuit abnormal situation by measuring whether the output signal of the output pin falls within the unexpected intermediate range, thus ensuring the functionality and reliability of the display device and improving maintenance efficiency.

Moreover, during the normal operation, the output signal SG may be switched between the gate high voltage VGH and the gate low voltage VGL. As rise time of the rising edge or fall time of the falling edge of the output signal is too long, the rising edge or the falling edge of the output signal may be misjudged as an occurrence of the short circuit condition since the voltage level of the rising edge or the falling edge of the output signal may fall within the range between the first reference voltage VRA and the second reference voltage VRB. As a result, a wrong detection result may be obtained due to waveform hysteresis or interference during transient switching period (e.g., rising edge or falling edge of the output signal. Please further refer to FIG. 2 and FIG. 3, the deglitch circuit 406 is coupled to the logic circuit 404 and configured to receive the detection result DT. The deglitch circuit 406 may generate a deglitched detection result DDT according to the detection result DT. The deglitch circuit 406 may remove any detection result that is determined based on a rising edge or a falling edge of the output signal from the detection result DT, so as to generate a deglitched detection result DDT.

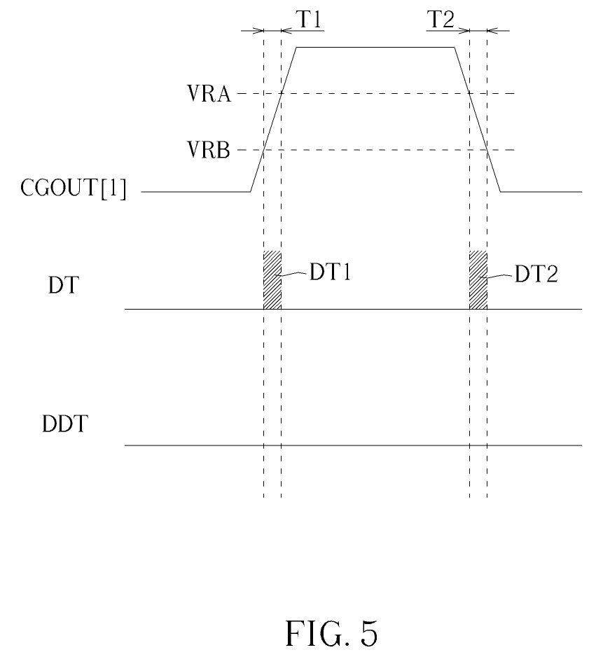

For example, please refer to FIG. 5. FIG. 5 is a schematic diagram illustrating operations of the deglitch circuit in the detection circuit according to an embodiment of the present invention. As shown in FIG. 5, the detection result DT generated by the logic circuit 404 includes detection results DT1 and DT2. The detection results DT1 and DT2 indicate that the short circuit condition occurs between the output pin CGOUT[1] and its adjacent pins. Since the voltage level of the output signal during a rise time period T1 (rising edge) is within the range between the first reference voltage VRA and the second reference voltage VRB, the logic circuit 404 may generate the detection result DT1 indicating the occurrence of the short circuit condition according to the voltage level of the output signal during the rise time period T1 (rising edge), thus causing a detection error. Similarly, as the voltage level of the output signal during a fall time period T2 (falling edge) is within the range between the first reference voltage VRA and the second reference voltage VRB, the logic circuit 404 may generate the detection result DT2 indicating the occurrence of the short circuit condition according to the voltage level of the output signal during the fall time period T2 (falling edge).

As shown in FIG. 5, the deglitch circuit 406 may remove detection results DT1 and DT2 which are determined based on the rising edge during rise time period T1 and/or the falling edge during the fall time period T2 of the output signal from the detection result DT, so as to generate deglitched detection result DDT. As such, the deglitched detection result DDT would not contain the wrong detection results DT1 DT2, the wrong detection results would be filtered out from the detection result DT to obtain the deglitched detection result DDT. That is, detection results caused by waveform hysteresis or interference during transient conditions would be ignored. Therefore, the deglitch circuit 406 of the embodiments may eliminate and correct the detection errors caused by transient switching period (rising edge or falling edge), and thus significantly improving the accuracy of short circuit detection.

In order to ensure the detection accuracy and avoid unwanted detection error, in some embodiment, the counter circuit 408 may be utilized for determining whether the short circuit condition exactly occurs on the detected output pin. Please further refer to FIG. 2 and FIG. 3, the counter circuit 408 is coupled to the deglitch circuit 406 and configured to receive deglitched detection result DDT. The counter circuit 408 may generate an advanced detection result according to the deglitched detection result DDT. The counter circuit 408 may determine whether the short circuit condition occurs on the output pin CGOUT[1] in a predetermined number of consecutive frame periods according to the deglitched detection result DDT. The counter circuit 408 may determine whether the short circuit condition occurs on the output pin CGOUT[1] for each frame period according to the deglitched detection result DDT. When determining that the short circuit condition occurs on the output pin CGOUT[1] in the predetermined number of consecutive frame periods, the counter circuit 408 may generate an advanced detection result indicating that the short circuit condition exactly occurs on the output pin CGOUT[1]. As such, the counter circuit 408 may report the advanced detection result to the display device 1 for following operation. When determining that the short circuit condition does not occur on the output pin CGOUT[1] in the predetermined number of consecutive frame periods, the counter circuit 408 may generate an advanced detection result indicating that no short circuit condition occurs on the output pin CGOUT[1]. The counter circuit 408 may not report the advanced detection result to the display device 1.

In an alternative embodiment, the counter circuit 408 may be coupled to the logic circuit 404 for receiving the detection result DT and generate an advanced detection result according to the detection result DT. The counter circuit 408 may determine whether the short circuit condition occurs on the output pin CGOUT[1] in a predetermined number of consecutive frame periods according to the detection result DT.

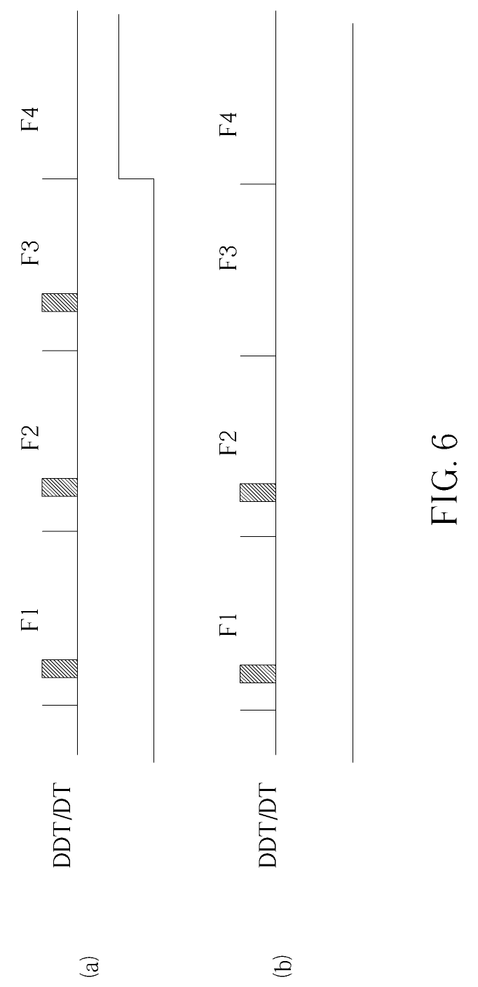

Please refer to FIG. 6, which is a schematic diagram illustrating operations of the counter circuit in the detection circuit according to an embodiment of the present invention. For example, the predetermined number of consecutive frame periods could be set to be three consecutive frame periods. As shown in the part (a) of FIG. 6, the deglitched detection result DDT (or the detection result DT) indicates that the short circuit condition occurs on the output pin CGOUT[1] in the frame periods F1, F2 and F3.. Therefore, the counter circuit 408 may determine that the short circuit condition occurs on the output pin CGOUT[1] in three consecutive frame periods (e.g., frame periods F1 to F3) according to the deglitched detection result DDT or the detection result DT, this means that the short circuit condition on the output pin CGOUT[1] has been detected for at least three consecutive frame periods, such that the counter circuit 408 may generate an advanced detection result indicating that the short circuit condition exactly occurs on the output pin CGOUT[1].

As shown in the part (b) of FIG. 6, the deglitched detection result DDT (or the detection result DT) indicates that the short circuit condition occurs on the output pin CGOUT[1] in the frame periods F1 and F2 (e.g. two consecutive frame periods which is shorter than three consecutive frame periods). The deglitched detection result DDT (or the detection result DT) indicates that no short circuit condition occurs on the output pin CGOUT[1] in the frame periods F3 and F4. Therefore, the counter circuit 408 may determine that no short circuit condition occurs on the output pin CGOUT[1] in three consecutive frame periods according to the deglitched detection result DDT or the detection result DT, this means that there is a detection error, such that the counter circuit 408 may generate an advanced detection result indicating that no short circuit condition exactly occurs on the output pin CGOUT[1].

Note that the predetermined number of consecutive frame periods to be set as three consecutive frame periods shown in FIG. 6 is one of various implementations of the present invention. In another embodiment, the predetermined number can be any number greater than or equal to two which can be set in advance. The predetermined number can also be set according to various design requirements and/or implementation requirements.

Therefore, based on the operations of the comparison circuit 402 and the logic circuit 404, the embodiments of the present invention can determine the occurrence of short circuit condition according to the output signal of the output pin. Moreover, the embodiments of the present invention offer a more accurate way to verify the short circuit detection result by utilizing the deglitch circuit 406 and/or the counter circuit 408. In some embodiments, the present invention can provide the deglitch circuit 406 to eliminate the detection errors caused by transient switching period, so as to significantly improve the accuracy of short circuit detection. The present invention can also provide the counter circuit 408 to check whether the short circuit detection results are completely correct in order to ensure the accuracy of short circuit detection.

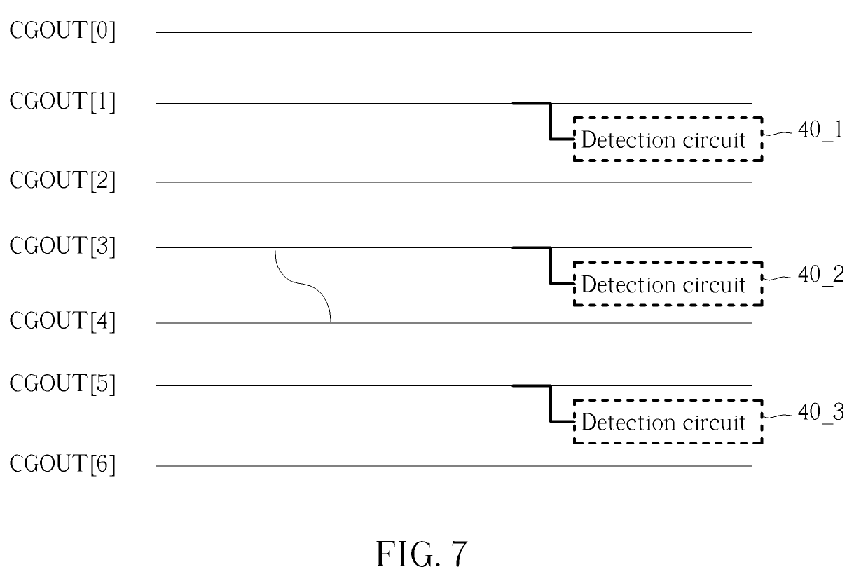

Furthermore, the detection circuit of embodiments of the invention is able to detect whether a short circuit condition occurs for each two adjacent output pin. Therefore, as half the number of output pins of the driving circuit 20 are equipped with corresponding detector circuits. The detection circuits may accurately determine which output pin in the driving circuit 20 is short-circuited. For example, the detection circuits may be disposed with odd number or even number of the output pins in the driving circuit 20. For example, please refer to FIG. 7 is a schematic diagram illustrating arrangement of the detection circuits for the display device 2 according to an embodiment of the invention. The detection circuits 40_1 to 40_3 may respectively be coupled to the odd number of the output pins CGOUT[1], CGOUT[3] and CGOUT[5] (e.g., the even number of output pins) of the driving circuit 20 for determining which output pin of the driving circuit 20 is short circuited with its adjacent output pin based on the output signals of the output pins. Conventional detection method may only determine that a short circuit occurs among the output pins in the driving circuit without exactly determining which output pin to be short-circuited. In comparison, the detection circuit of embodiments of the invention may accurately determine which output pin of the driving circuit 20 is short-circuited.

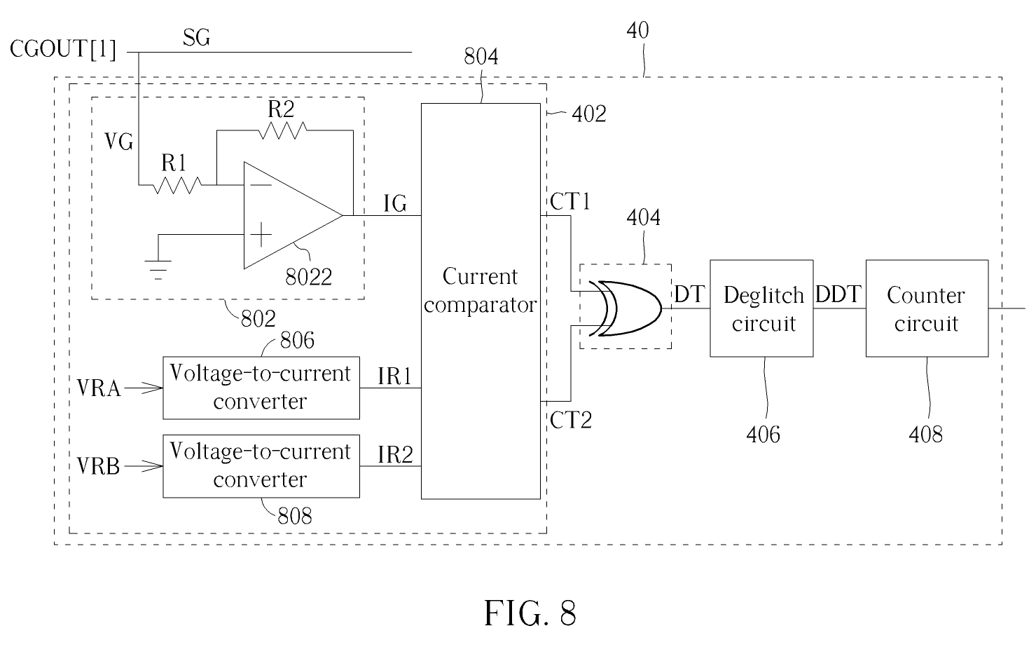

Please refer to FIG. 8. FIG. 8 is a schematic diagram of the detection circuit 40 of the display device 2 shown in FIG. 2 according to an alternative embodiment of the present invention. Please note that the units in the detection circuit 40 shown in FIG. 8 with the same designations as those in the detection circuit 40 shown in FIG. 3 have similar operations and functions, further description is omitted for brevity. The interconnections of the units are as shown in FIG. 8. For brevity of description, the detection circuit 40 is assumed to be coupled to an output pin (e.g., output pin CGOUT[1]) of the driving circuit 20 and detect whether a short circuit condition occurs between the output pin CGOUT[1] and its adjacent pin. The first reference signal may be a first reference current IRA, and the second reference signal may be a second reference current IRB. As shown in FIG. 8, the comparison circuit 402 includes voltage to current converters 802, 806 and 808, and a current comparator 804. The voltage to current converter 802 is coupled to the output pin CGOUT[1] of the driving circuit 20 and configured to receive an output signal SG from the output pin CGOUT[1] of the driving circuit 20 and convert a voltage VG of the output signal SG into a current IG. The voltage to current converter 806 is configured to receive a first reference voltage VRA and convert the first reference voltage VRA into a first reference current IR1. The voltage to current converter 808 is configured to receive a second reference voltage VRB different from the first reference voltage VRA and convert the second reference voltage VRB into a second reference current IR2. For example, the first reference voltage VRA may be greater than the second reference voltage VRB. The first reference current IR1 may be greater than the second reference current IR2. The output signal SG may be switched between the gate high voltage VGH and the gate low voltage VGL during normal operation. Moreover, the current comparator 804 is coupled to the current converters 802, 806 and 808. The current comparator 804 is configured to compare the current IG of the output signal SG with the first reference current IR1 to generate a comparison result CT1, and output the comparison result CT1 to the logic circuit 404. The current comparator 804 is configured to compare the current IG of the output signal SG with the second reference current IR2 to generate a comparison result CT2, and output the comparison result CT2 to the logic circuit 404.

In an embodiment, the voltage to current converters 802 may include an operational amplifier 8022 and resistors R1 and R2. A first terminal of the resistor R1 is coupled to the output pin CGOUT [1] of the driving circuit 20 to receive an output signal SG from the output pin CGOUT[1] of the driving circuit 20. A second terminal of the resistor R1 is coupled to an inverting input terminal of the operational amplifier 8022. The resistor R2 is coupled between the inverting input terminal and an output terminal of the operational amplifier 8022. A non-inverting terminal of the operational amplifier 8022 is coupled to a ground terminal, and the output terminal of the operational amplifier 8022 is configured to output the current IG to the current comparator 804. In an embodiment, the voltage to current converters 802, 806 and 808 may be realized by the same circuit architecture.

In an embodiment, when the comparison result CT1 of the comparator 4022 indicates that the current IG of the output signal SG is greater than or equal to the first reference current IR1 and the second comparison result CT2 of the comparator 4024 indicates that the current IG of the output signal SG is greater than the second reference current IR2, this means that the current IG of the output signal SG is outside the range between the first reference current IR1 and the second reference current IR2 since the first reference current IR1 is greater than the second reference current IR2. Accordingly, the logic circuit 404 generates the detection result DT indicating that no short circuit condition occurs between the output pin CGOUT[1] and its adjacent pins. In another embodiment, when the comparison result CT1 of the comparator 4022 indicates that the current IG of the output signal SG is smaller than the first reference current IR1 and the second comparison result CT2 of the comparator 4024 indicates that the current IG of the output signal SG is smaller than or equal to the second reference current IR2, this means that the current IG of the output signal SG is outside the range between the first reference current IR1 and the second reference current IR2. Thus, the logic circuit 404 generates the detection result DT indicating that no short circuit condition occurs between the output pin CGOUT[1] and its adjacent pins. In another embodiment, when the comparison result CT1 of the comparator 4022 indicates that the current IG of the output signal SG is smaller than the first reference current IR1 and the second comparison result CT2 of the comparator 4024 indicates that the current IG of the output signal SG is greater than the second reference current IR2, this means that the current IG of the output signal SG falls within the range between the first reference current IR1 and the second reference current IR2 since the first reference current IR1 is greater than the second reference current IR2. Therefore, the logic circuit 404 generates the detection result DT indicating that a short circuit condition occurs between the output pin CGOUT[1] and its adjacent pins.

To sum up, since the impedance between two adjacent output pins changes, the two pins would be short-circuited with each other, so that the output voltage or signal amplitude will be pulled to an unexpected intermediate level. Therefore, the embodiments of the present invention can provide the comparison circuit 402 and the logic circuit 404 to determine the presence of a short circuit abnormal situation by measuring whether the output signal of the output pin falls within the unexpected intermediate range, so as to ensure the functionality and reliability of the display device, and improve maintenance efficiency. More particularly, under the processing of the deglitch circuit and the counter circuit of the embodiments, the short circuit condition may be detected more accurately, and thus ensuring the detection accuracy and avoiding unwanted detection error.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A detection circuit for a driving circuit, comprising:
a comparison circuit, coupled to an output pin of the driving circuit, and configured to receive an output signal from the output pin of the driving circuit, compare the output signal with a first reference signal level to generate a first comparison result, and compare the output signal with a second reference signal level to generate a second comparison result, wherein the first reference signal level is different from the second reference signal level; and
a logic circuit, coupled to the comparison circuit, and configured to generate a detection result according to the first comparison result and second comparison result in order to indicate whether a short circuit condition occurs between the output pin and an adjacent output pin of the driving circuit.

2. The detection circuit of claim 1, wherein the first reference signal level is greater than the second reference signal level, wherein when the first comparison result indicates that a signal level of the output signal is small than the first reference signal level and the second comparison result indicates that the signal level of the output signal is greater than the second reference signal level, the logic circuit generates the detection result indicating that the short circuit condition occurs between the output pin and the adjacent pin of the driving circuit.

3. The detection circuit of claim 1, wherein the first reference signal level is a first reference voltage and the second reference signal level is a second reference voltage, wherein the comparison circuit comprises:
a first comparator, coupled to the output pin of the driving circuit, and configured to receive the output signal and compare a voltage of the output signal with the first reference voltage to output the first comparison result; and
a second comparator, coupled to the output pin of the driving circuit, and configured to receive the output signal and compare the voltage of the output signal with the second reference voltage to output the second comparison result, wherein the second reference voltage is different from the first reference voltage.

4. The detection circuit of claim 3, wherein the first reference voltage is greater than the second reference voltage, wherein when the first comparison result indicates that the voltage of the output signal is small than the first reference voltage and the second comparison result indicates that the voltage of the output signal is greater than the second reference voltage, the logic circuit generates the detection result indicating that the short circuit condition occurs between the output pin and the adjacent pin of the driving circuit.

5. The detection circuit of claim 3, wherein the first reference voltage is smaller than a gate high voltage and the second reference voltage is greater than a gate low voltage.

6. The detection circuit of claim 1, wherein the first reference signal level is a first reference current, and the second reference signal level is a second reference current, and the second reference current is different from the first reference current, wherein the comparison circuit comprises:
a first voltage to current converter, coupled to the output pin of the driving circuit, and configured to receive the output signal and convert a voltage of the output signal into a current of the output signal;
a second voltage to current converter, configured to receive a first reference voltage and convert the first reference voltage into the first reference current;
a third voltage to current converter, configured to receive a second reference voltage and convert the second reference voltage into the second reference current, wherein the second reference current is different from the first reference current; and
a current comparator, coupled to the first voltage to current converter, the second voltage to current converter and the third voltage to current converter, and configured to compare the current of the output signal with the first reference current to output the first comparison result and compare the current of the output signal with the second reference current to output the second comparison result.

7. The detection circuit of claim 3, wherein the first reference current is greater than the second reference current, wherein when the first comparison result indicates that the current of the output signal is small than the first reference current and the second comparison result indicates that the current of the output signal is greater than the second reference current, the logic circuit generates the detection result indicating that the short circuit condition occurs between the output pin and the adjacent pin of the driving circuit.

8. The detection circuit of claim 1, wherein the logic circuit comprises:
an exclusive or gate (XOR) gate circuit, coupled to the comparison circuit and configured to generate the detection result according to the first comparison result and second comparison result.

9. The detection circuit of claim 1, further comprising:
a deglitch circuit, coupled to the logic circuit and configured to generate a deglitched detection result according to the detection result generated by the logic circuit, wherein the deglitch circuit generates the deglitched detection result by removing a detection result that is determined based on a rising edge or a falling edge of the output signal from the detection result generated by the logic circuit.

10. The detection circuit of claim 1, further comprising:
a counter circuit, configured to determine whether the short circuit condition occurs on the output pin in a predetermined number of consecutive frame periods according to the detection result or a deglitched detection result and accordingly generate an advanced detection result.

11. A detection method for a driving circuit, comprising:
receiving an output signal from an output pin of the driving circuit;
comparing the output signal with a first reference signal level to generate a first comparison result;
comparing the output signal with a second reference signal level to generate a second comparison result, wherein the first reference signal level is different from the second reference signal level; and
generating a detection result according to the first comparison result and second comparison result in order to indicate whether a short circuit condition occurs between the output pin and an adjacent output pin of the driving circuit.

12. The detection method of claim 11, wherein the first reference signal level is greater than the second reference signal level, wherein detection method further comprising:
when the first comparison result indicates that a signal level of the output signal is small than the first reference signal level and the second comparison result indicates that the signal level of the output signal is greater than the second reference signal level, generating the detection result indicating that the short circuit condition occurs between the output pin and the adjacent pin of the driving circuit.

13. The detection method of claim 11, wherein the first reference signal level is a first reference voltage and the second reference signal level is a second reference voltage, wherein detection method further comprising:
comparing a voltage of the output signal with the first reference voltage to output the first comparison result; and
comparing the voltage of the output signal with the second reference voltage to output the second comparison result, wherein the second reference voltage is different from the first reference voltage.

14. The detection method of claim 13, wherein the first reference voltage is greater than the second reference voltage, wherein detection method further comprising:
when the first comparison result indicates that the voltage of the output signal is small than the first reference voltage and the second comparison result indicates that the voltage of the output signal is greater than the second reference voltage, generating the detection result indicating that the short circuit condition occurs between the output pin and the adjacent pin of the driving circuit.

15. The detection method of claim 13, wherein the first reference voltage is smaller than a gate high voltage and the second reference voltage is greater than a gate low voltage.

16. The detection method of claim 11, wherein the first reference signal level is a first reference current and the second reference signal level is a second reference current, wherein detection method further comprising:
converting a voltage of the output signal into a current of the output signal;
converting a first reference voltage into the first reference current;
converting a second reference voltage into the second reference current, wherein the second reference current is different from the first reference current; and
comparing the current of the output signal with the first reference current to output the first comparison result and compare the current of the output signal with the second reference current to output the second comparison result.

17. The detection method of claim 13, wherein the first reference current is greater than the second reference current, wherein detection method further comprising:
when the first comparison result indicates that the current of the output signal is small than the first reference current and the second comparison result indicates that the current of the output signal is greater than the second reference current, generating the detection result indicating that the short circuit condition occurs between the output pin and the adjacent pin of the driving circuit.

18. The detection method of claim 11, further comprising:
generating, by an exclusive or gate (XOR) gate circuit, the detection result according to the first comparison result and second comparison result.

19. The detection method of claim 11, further comprising:
generating a deglitched detection result by removing a detection result that is determined based on a rising edge or a falling edge of the output signal from the detection result generated based on the first comparison result and second comparison result.

20. The detection method of claim 11, further comprising:
determining whether the short circuit condition occurs on the output pin in a predetermined number of consecutive frame periods according to the detection result or a deglitched detection result and accordingly generating an advanced detection result.
